(19) United States
(12) Patent Application Publication
(10) Pub. No.: US 2008/0038526 A1
(43) Pub. Date: Feb. 14, 2008

(54) Silicon Epitaxial Wafer And Manufacturing Method Thereof

(75) Inventors: Fumitaka Kume, Annaka-shi (JP); Tomosuke Yushida, Annaka-shi (JP); Ken Aihara, Annaka-shi (JP); Ryoji Hoshi, Nishishirakawa-gun (JP); Satoshi Tobe, Annaka-shi (JP); Naohisa Toda, Annaka-shi (JP); Fumio Tahara, Annaka-shi (JP)

Correspondence Address: SNIDER & ASSOCIATES, P. O. BOX 27613, WASHINGTON, DC, 20038-7613, US

(73) Assignee: Shin-Etsu Handotai Co., Ltd., Tokyo (JP)

(21) Appl. No.: 11/632,719

(22) PCT Filed: Jul. 5, 2005
(86) PCT No.: PCT/JP05/12379

§ 371 Date: Jan. 18, 2007

(30) Foreign Application Priority Data
Jul. 22, 2004 (JP) 2004-214895

(51) Int. Cl. B32B 7/02; C30B 15/00

(52) U.S. Cl. 428/218; 117/21

(57) ABSTRACT

A silicon epitaxial wafer 100 formed by growing a silicon epitaxial layer 2 on a silicon single crystal substrate 1, produced by a CZ method, and doped with boron so that a resistivity thereof is in the range of 0.009 Ω·cm or higher and 0.012 Ω·cm or lower. The silicon single crystal substrate 1 has a density of the oxygen precipitation nuclei of 1×10¹⁰ cm⁻³ or higher. A width of a no-oxygen-precipitation-nucleus-forming-region 15, formed between the silicon epitaxial layer 2 and the silicon single substrate 1, is in the range of more than 0 μm and less than 10 μm. Thereby, provided is a silicon epitaxial wafer using a boron doped p⁺ CZ substrate, wherein a formed width of no-oxygen-precipitation-nucleus-forming-region is reduced sufficiently, and oxygen precipitates can be formed having a density sufficient enough to exert an IG effect.

### BACKGROUND OF THIS INVENTION

1. Field of this Invention

This invention relates to a silicon epitaxial wafer obtained by vapor phase growing of a silicon epitaxial layer on a silicon single crystal substrate to which boron is added at a comparatively high concentration, and to a manufacturing method thereof.

2. Description of the Related Art

A silicon epitaxial wafer obtained by vapor phase growing of a silicon epitaxial layer on a silicon single crystal substrate (hereinafter referred to as p⁺CZ substrate) produced by means of a Czochralski method (hereinafter referred to simply as CZ method) and having boron added at a comparatively high concentration, so that a resistivity thereof is 0.02 Ω·cm or less, has been widely employed for, for example, latch-up prevention or formation of a defect free device forming region.

Many of oxygen precipitation nuclei are formed in a p⁺ CZ substrate during cooling to room temperature after solidification as crystal in a crystal pulling step. A size of an oxygen precipitation nucleus is very small and usually 1 nm or less. A precipitation nucleus grows to an oxygen precipitate if the precipitation nucleus is held at a temperature in the range of a nucleus formation temperature or higher and a critical temperature of re-solid solution in a silicon single crystal bulk or less. The oxygen precipitate is one kind of crystal defects referred to BMD (Bulk Micro Defect) and works as an adverse factor such as lowering in withstand voltage or current leakage; therefore, it is desired that an oxygen precipitate is formed in a device formation region at the lowest possible level. In a substrate region that is not used for device formation, however, the oxygen precipitates can be effectively used as getters for heavy metal components in a device fabrication process; therefore, in a case of a silicon epitaxial wafer as well, oxygen precipitates have been intentionally formed in a silicon single crystal substrate for the growth thereof at a concentration in the range where no problem such as bow occurs. A gettering effect acting on heavy metals by such an oxygen precipitate is referred to as an IG (Intrinsic Gettering) effect.

It has been known that a precipitation nucleus of an oxygen precipitate, being retained higher than the above critical temperature, is annihilated by re-solid solution in a silicon single crystal bulk. Since a silicon epitaxial wafer is manufactured with a vapor phase growth step for a silicon epitaxial layer, which is a high temperature annealing of 1100° C. or higher, many of existing oxygen precipitation nuclei prior to vapor phase growth are annihilated in the course of a thermal history of the vapor phase growth. With fewer precipitation nuclei, formation of oxygen precipitates is suppressed in a semiconductor device fabrication process even if an initial oxygen concentration of a silicon single crystal is high, and thus an IG effect can not be expected much.

In order to solve this problem, a method has been proposed in which oxygen precipitation nuclei are newly produced in a p⁺ CZ substrate by applying low temperature annealing at a temperature in the range of 450° C. or higher and 750° C. or lower to a silicon epitaxial wafer and thereafter, medium temperature annealing (in the range between low temperature annealing and high temperature annealing) is applied to thereby grow oxygen precipitates (JP-A Nos. 9-283529 and 10-270455, and WO 01/056071). Another method has been proposed in JP-A No. 9-283529 in which oxygen precipitation nuclei or oxygen precipitates are formed in a p⁺ CZ substrate and thereafter, a silicon epitaxial layer is grown in a vapor phase so as to manufacture a silicon epitaxial wafer.

The inventors of this invention have studied the proposal and found the following problem arising in low temperature annealing for formation of oxygen precipitation nuclei in a silicon epitaxial wafer in a case where a p⁺ CZ substrate is adopted. That is, in a case where a quantity of added boron is slightly lower as described above, interstitial oxygen atoms in the p⁺ CZ substrate out-diffuse through a silicon epitaxial layer and thereby a region, where no oxygen precipitation nucleus (no-oxygen-precipitation-nucleus-forming-region) is produced, is formed in the surface layer portion serving as an interface between the silicon epitaxial layer and the p⁺ CZ substrate. Almost no BMDs such as oxygen precipitate or bulk stacking faults are formed in the no-oxygen-precipitation-nucleus-forming-region by subsequent medium annealing so as to finally become a MDB free layer (hereinafter also referred to as DZ (Denuded Zone) layer). A BMD free layer has no gettering capability described above. In a device fabrication process using a silicon epitaxial wafer, a diffusion velocity of a heavy metal impurity is decreased at a lower treatment temperature, and therefore a larger part of heavy metal impurity remains on a wafer surface in a case where the heavy metal impurity adheres onto a silicon epitaxial wafer during the device fabrication process. In this sense, it is desirable that oxygen precipitates having a gettering capability are produced at a higher possible level in a region very close to a silicon epitaxial layer, which is a device forming region.

In order to form oxygen precipitates, however, a certain amount of oxygen precipitation nuclei are required and almost all of the oxygen precipitation nuclei are lost in an epitaxial growth step; therefore, the low temperature annealing is essentially required in order to restore the original state so as to have the certain amount of oxygen precipitation nuclei. Application of the low temperature annealing leads to formation of a BMD free layer direct under the silicon epitaxial layer at a higher level, resulting in a dilemma in which a gettering effect for a heavy metal impurity is impaired against expectation. Therefore, it is very important to narrow a width of a BMD free layer (no-oxygen-precipitation-nucleus-forming-region) formed in the substrate region direct under the epitaxial layer, in a device fabrication process which has a tendency of lowering the temperature, in order to avoid contamination by a heavy metal, whereas this problem has been conventionally neglected without a special attention paid thereto and a study for solving the problem has not been emphasized so much.

It is an object of this invention to provide a silicon epitaxial wafer in which a boron doped p⁺ CZ substrate is used, a formed width of a no-oxygen-precipitation-nucleus-forming-region is reduced sufficiently and an oxygen precipitation region with a density sufficient to exert an IG effect can be formed, and to a manufacturing method thereof.

### SUMMARY OF THIS INVENTION

A silicon epitaxial wafer of this invention is provided in order to solve the above problems and the silicon epitaxial wafer is a silicon epitaxial wafer formed by growing a silicon epitaxial layer on a silicon single crystal substrate, produced by means of a CZ method, and doped with boron so that a resistivity thereof is in the range of 0.009 Ω·cm or higher and 0.012 Ω·cm or lower and

the silicon single crystal substrate has not only oxygen precipitation nuclei at a density of 1×10¹⁰ cm⁻³ or higher, but also a width of a no-oxygen-precipitation-nucleus-forming-region, which is formed in the surface portion serving as the interface between the silicon epitaxial layer and the silicon single crystal substrate, is in the range of more than 0 μm and less than 10 μm.

In a silicon epitaxial wafer using a boron doped p⁺ CZ substrate, it is necessary to form oxygen precipitation nuclei at a density of 1×10¹⁰ cm⁻³ or higher in a silicon single crystal substrate thereof in order to obtain a sufficient IG effect in a device fabrication process. Since the oxygen precipitation nuclei is annihilated, as described above, in the vapor phase growth step, it is necessary to apply low temperature annealing to the silicon epitaxial wafer so as to have a required density of formed nuclei in order to secure an IG effect. By this low temperature annealing, Interstitial oxygen atoms in the p⁺ CZ substrate outdiffuse through the silicon epitaxial layer, so as to form a region where no oxygen precipitation nucleus is formed (no-oxygen-precipitation-nucleus-forming-region) in a surface portion of the substrate. Since a conventional low temperature annealing has been conducted at a temperature in the range of 450° C. or higher and 750° C. or lower for 3 hr or longer, a width of the no-oxygen-precipitation-nucleus-forming-region tends to be 10 μm or more. To the contrary, in case where a low temperature annealing is applied in the range of 450° C. or higher and 750° C. or lower for a time less than 3 hr, a width of the no-oxygen-precipitation-nucleus-forming-region formed by this low temperature annealing can be suppressed to 10 μm. In this case, however, it is impossible to stably form oxygen precipitation nuclei at a density of 1×10¹⁰ cm⁻³ or higher.

Considering this circumstances, in this invention, a silicon single crystal substrate, for manufacturing a silicon epitaxial wafer, is intentionally used that is produced by means of a CZ method and doped with boron so as to obtain a resistivity of 0.012 Ω·cm or lower, based on the fact that a boron doped p⁺ CZ substrate with a lower resistivity allows oxygen precipitation nuclei to be produced easier. As a result, it is possible not only to form oxygen precipitation nuclei at a density of 1×10¹⁰ cm⁻³ or higher, so as that a sufficient gettering effect can be expected, but also to suppress a width of a no-oxygen-precipitation-nucleus-forming-region to less than 10 μm, that is formed in the surface portion serving as the interface between the silicon single crystal substrate and the silicon epitaxial layer. A silicon epitaxial wafer having a boron doped p⁺CZ substrate can be realized, wherein oxygen precipitation nuclei are produced at a required density, a formed width of a no-oxygen-precipitation-nucleus-forming-region is decreased, and an IG effect can be sufficiently exerted in a vicinity of the silicon epitaxial layer serving as a device forming region.

A manufacturing method of a silicon epitaxial wafer of this invention includes: a vapor phase growth step of vapor phase growing of a silicon epitaxial layer on a silicon single crystal substrate, produced by means of a CZ method, and doped with boron so that a resistivity thereof is in the range of 0.009 Ω·cm or higher and 0.012 Ω·cm or lower; and

low temperature annealing conducted at a temperature in the range of 450° C. or higher and 750° C. or lower so that oxygen precipitation nuclei are produced at a density in the range of 1×10¹⁰ cm⁻³ or higher and less than 1×10¹¹ cm⁻³ in the silicon single crystal substrate after the vapor phase growth step.

As a silicon single crystal substrate for manufacturing an silicon epitaxial wafer, the substrate doped with boron, so as to have a resistivity of 0.012 Ω·cm or lower, is intentionally employed and thereby, oxygen precipitation nuclei can be produced at a density of 1×10¹⁰ cm⁻³ or higher, at which a sufficient gettering effect can be expected, even if low temperature annealing is applied in the range of 450° C. or higher and 750° C. or lower for, for example, less than 3 hr to the silicon epitaxial wafer obtained by vapor phase growing of a silicon epitaxial layer on the silicon single crystal substrate. Since the low temperature annealing time is reduced, a width of a no-oxygen-precipitation-nuclei-forming-region at the interface between the silicon epitaxial layer and the silicon single crystal substrate can remain less than 10 μm. Since it does not mean that the low temperature annealing is not conducted at all, the no-oxygen-precipitation-nuclei-forming-region is formed, though, in a small width (a width greater than 0 μm).

With a resistivity of a substrate for use higher than 0.012 Ω·cm, it is difficult to keep a formed width of a no-oxygen-precipitation-nucleus-forming-region at less than 10 μm. On the other hand, since excessive increase in a density of formation of oxygen precipitates can suppress bow of a substrate, a resistivity of the substrate is desirably set to 0.09 Ω·cm or higher.

An initial oxygen concentration in a silicon single crystal substrate is preferably in the range of 6.5×10¹⁷ cm⁻³ or higher and 10×10¹⁷ cm⁻³ or lower. If an initial oxygen concentration is less than 6.5×10¹⁷ cm⁻³, it is difficult to sufficiently secure a density of formation of oxygen precipitation nuclei, so as that a sufficient IG effect can not be expected. Contrary to this, if an initial oxygen concentration exceeds 10×10¹⁷ cm⁻³, a density of formation of oxygen precipitation nuclei is excessively increased resulting in a higher possibility of rapid increase in deformation, such as bow or the like, of a wafer. Note that in this specification, a unit of a oxygen concentration is expressed using standards of JEIDA (an abbreviation of Japanese Electronic Industry Development Association, which has been altered to JEITA, an abbreviation of Japan Electronics and Information Technology Industries Association). Note that a density of oxygen precipitation nuclei is desirably less than 10×10¹¹ cm⁻³ in order to suppress deformation such as bow of a wafer.

### BRIEF DESCRIPTION OF THE DRAWINGS

FIG. 1 is a schematic view showing a silicon epitaxial wafer of this invention.

FIG. 2 is process views describing a manufacturing method of a silicon epitaxial wafer of this invention.

FIG. 3 is a graph showing a relationship between a substrate resistivity and a width of a no-oxygen-precipitation-nucleus-forming-region.

FIG. 4 is a graph showing a relationship between a substrate resistivity and a substrate initial oxygen concentration.

FIG. 5 is a graph showing a relationship between a substrate initial oxygen concentration and an oxygen precipitate density.

FIG. 6 is a graph showing a relationship between a substrate resistivity and an oxygen precipitate density.

### DETAILED DESCRIPTION OF THE PREFERRED EMBODIMENTS

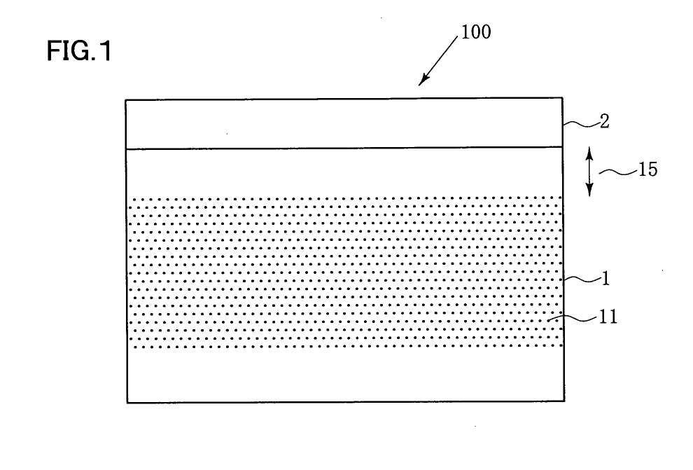

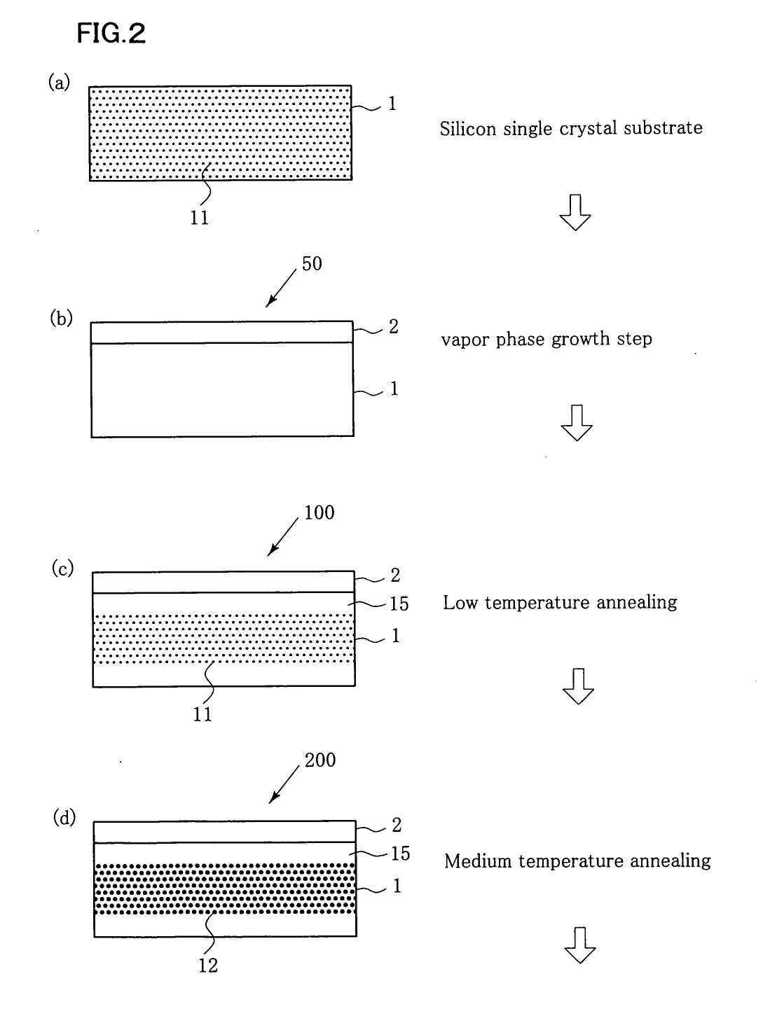

Descriptions will be explained below of the best mode for carrying out this invention using the accompanying drawings. In FIG. 1, there is schematically shown a silicon epitaxial wafer 100 of this invention. A silicon epitaxial wafer 100 of this invention is manufactured by vapor phase growing of a silicon epitaxial layer 2 at a temperature of 1100° C. or higher on a silicon single crystal substrate 1 doped with boron by a CZ method so that a resistivity thereof is in the range of 0.009 Ω·cm or higher and 0.012 Ω·cm or lower. A low temperature annealing is applied to the silicon epitaxial wafer 100 in the range of 4500° C. or higher and 750° C. or lower after the vapor phase growth, and a width of a no-oxygen-precipitation-nucleus-forming-region 15, formed in the surface portion serving as the interface between the silicon single crystal substrate 1 and the silicon epitaxial layer 2, is in the range of more than 0 μm and less than 10 μm. Medium temperature annealing is applied to the silicon epitaxial wafer 100 in the range higher than a temperature in the low temperature annealing and lower than a vapor phase growth temperature to thereby mature the oxygen precipitation nuclei 11 at a density of 1×10¹⁰ cm⁻³ or higher to oxygen precipitates 12 (FIG. 2).

An interstitial oxygen concentration in the silicon single crystal substrate 1 is controlled in the range of 6.5×10¹⁷ cm⁻³ or higher and 10×10¹⁷ cm⁻³ or lower. If an interstitial oxygen concentration does not reach 6.5×10¹⁷ cm⁻³, it is difficult to form oxygen precipitation nuclei 11 at a sufficient density in the silicon single crystal substrate 1 in the low temperature annealing in the range of 450° C. or higher and 750° C. or lower for a short time less than, for example, 3 hr after the vapor phase growth, and thereafter it is also difficult to produce oxygen precipitates 12 at a sufficient density in the medium temperature annealing, so as that a sufficient gettering effect can not be expected. To the contrary, if an interstitial oxygen concentration exceeds 10×10¹⁷ cm⁻³, oxygen precipitates 12 are excessively produced in the medium temperature annealing since large amounts of oxygen precipitation nuclei 11 are produced in the low temperature annealing, resulting in a higher possibility of rapid increase in deformation of the wafer. Note that in order to suppress deformation of the wafer, it is preferable to control densities of oxygen precipitation nuclei 11, and therefore oxygen precipitates 12 to a value less than 1×10¹¹ cm⁻³.

In FIG. 2, there is shown an outline of process views describing a manufacturing method of a silicon epitaxial wafer 100 of this invention. First a p⁺ CZ silicon single crystal substrate 1 (hereinafter referred to simply as a substrate 1) is prepared that is doped with boron, has a resistivity in the range of 0.009 Ω·cm or higher and 0.012 Ω·cm or lower, and further has an initial oxygen concentration in the range of 6.5×10¹⁷ cm⁻³ or higher and 10×10¹⁷ cm⁻³ or lower (FIG. 2(a)). In the substrate 1, there is oxygen precipitation nuclei 11 produced during a period from solidification of a silicon crystal to cooling down to room temperature in a crystal pulling step.

Then, a vapor phase growth step, of vapor phase growing of the silicon epitaxial layer 2 on the substrate 1 at a temperature of 1100° C. or higher, is conducted so as to obtain a silicon epitaxial wafer 50 (FIG. 2(b)). Since the vapor phase growth step is conducted at a high temperature of 1100° C. or higher, almost all of the oxygen precipitation nuclei 11 in the substrate 1 produced in the crystal pulling step turns to be in a solid solution state.

The silicon epitaxial wafer 50 is placed in a annealing furnace, not shown a figure, after the vapor phase growth step, and then applied to the low temperature annealing in the range of 450° C. or higher and 750° C. or lower for a given time in an oxidative atmosphere, to thereby re-produce oxygen precipitation nuclei 11 in the substrate 1, and so as to form a silicon epitaxial wafer 100 (FIG. 2(c)). In this process, a no-oxygen-precipitation-nucleus-forming-region 15 is formed with a width in the range more than 0 μm and less than 10 μm in the surface portion serving as the interface between the silicon single crystal substrate 1 and the silicon epitaxial layer 2. The oxidative atmosphere is an atmosphere which is composed of, for example, dry oxygen diluted with inert gas, such as nitrogen or the like, while the atmosphere may also be composed of 100% dry oxygen. The low temperature annealing at a temperature lower than 450° C. makes diffusion of interstitial oxygen extremely slower, and thus it is difficult to produce oxygen precipitation nuclei 11. If a temperature of the low temperature annealing exceeds 750° C., it is also difficult to produce oxygen precipitation nuclei 11 because of a lower super-saturation degree of the interstitial oxygen.

Oxygen precipitation nuclei 11 are matured into oxygen precipitates 12 by further applying the medium temperature annealing in the range of 800° C. or higher and lower than 1100° C., for example, in the device fabrication process (FIG. 2(d)). In such a way, a semiconductor wafer 200 can be provided, in which oxygen precipitates 12 are stably produced at a high concentration in a region in the range more than 0 μm and less than 10 μm from the interface with the silicon epitaxial layer 2 that is a device formation region.

### Example 1

Descriptions will be given more specifically with examples below. Note that an initial oxygen concentration in a silicon single crystal substrate 1 described in the example is usually expressed as a conversion of a measured value by means of an inert gas fusion method, based on a correlation between a Fourier transform infrared spectroscopy and an inert gas fusion method, obtained using a substrate with an ordinary resistivity in the range of 1 to 20 Ω·cm. A density of oxygen precipitation nuclei 11 is measured in the following way: the medium temperature annealing is further applied to the silicon epitaxial wafer 100 in which oxygen precipitation nuclei 11 have been produced to thereby mature the nuclei 11 into oxygen precipitates 12 and thereafter, the silicon epitaxial wafer is applied to selective etching using an etching solution including hydrofluoric acid (with a concentration in the range of 49 to 50 wt %): nitric acid (with a concentration in the range of 60 to 62 wt %): acetic acid (with a concentration in the range of 99 to 100 wt %): water=1:15:6:6 (in volume ratio) and then a density of oxygen precipitation nuclei 11 is measured with an optical microscope of a magnification in the range of ×500 to ×1000. By using the etching solution with this composition, even fine oxygen precipitates 12 can be clearly observed.

First of all, a boron doped silicon single crystal substrate 1 with a resistivity of 0.012 Ω·cm and an initial oxygen concentration of 6.8×10¹⁷ cm⁻³ (13.6 ppma) is prepared, and a silicon epitaxial layer 2 with a resistivity of 20 Ω·cm and a thickness of 5 μm is grown in a vapor phase on a main surface (100) of the substrate 1 at a temperature of 1100° C., so as to obtain a silicon epitaxial wafer 50.

Then, a low temperature annealing for producing oxygen precipitation nuclei is conducted on the silicon epitaxial wafer 50 at a temperature of 650° C. for 1 hr in an oxidative atmosphere composed of 3% oxygen and 97% nitrogen, so as to obtain the silicon epitaxial wafer 100. Thereafter, medium temperature annealing was applied in conditions of 800° C. for 4 hr and 1000° C. for 16 hr, so as to grow oxygen precipitates 12, and then a density of oxygen precipitation nuclei and a width of no-oxygen-precipitation-nuclei-forming-region were evaluated, so as to obtain the following results that the density of oxygen precipitation was 1.3×10¹⁰ cm⁻³ and the width of the no-oxygen-precipitation-nuclei-forming-region was 6 μm.

Note that. After obtaining the silicon epitaxial wafer 50 in the same conditions as in Example 1 for comparison, medium temperature annealing in conditions of 800° C. for 4 hr and 1000° C. for 16 hr was conducted without applying low temperature annealing in conditions of 650° C. for 1 hr, so as to result that no oxygen precipitation nuclei 11 was formed. On the other hand, vapor phase growth and annealing were conducted in the same conditions as in Example 1 with an exception of use of a boron doped silicon single crystal substrate 1 having a resistivity of 0.016 Ω·cm and an initial oxygen concentration of 5.9×10¹⁷ cm⁻³ (11.9 ppma), so as to result that no oxygen precipitation nuclei was produced, as expected. Vapor phase growth and annealing were conducted in the same conditions as in Example 1 with an exception of use of a boron doped silicon single crystal substrate 1 having a resistivity of 0.015 Ω·cm and an initial oxygen concentration of 6.6×10¹⁷ cm⁻³ (13.1 ppma) and application of low temperature annealing at a temperature of 650° C. for 4 hr, so as to result that a density of the oxygen precipitation nuclei was decreased to 3.5×10⁹ cm⁻³, and a width of the no-oxygen-precipitation-nucleus-forming-region 15 was increased to 25 μm.

### Example 2

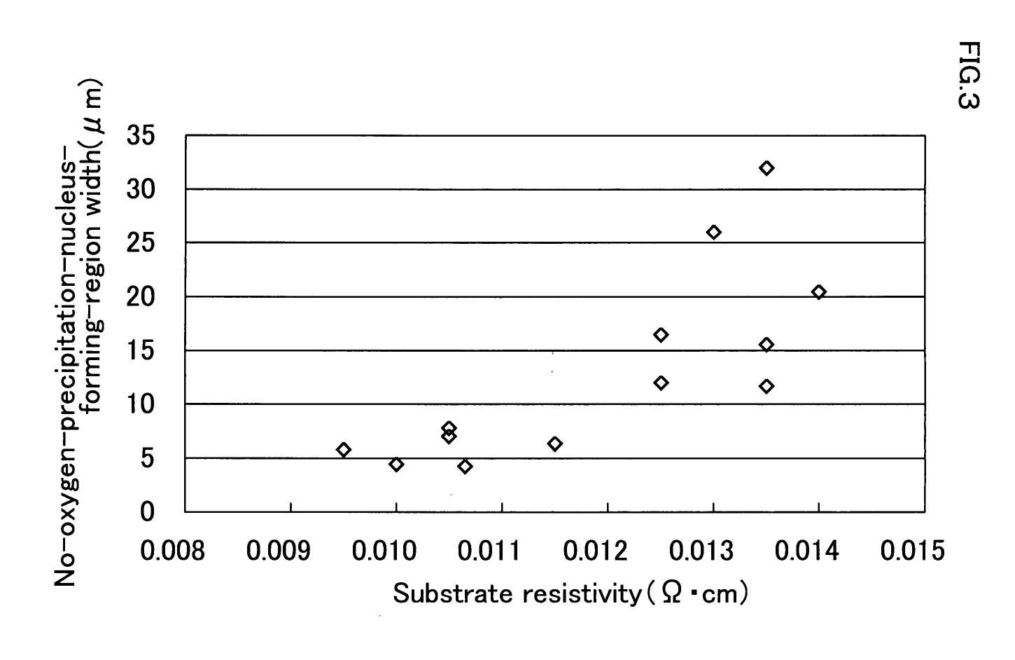

In FIG. 3, there is shown a relationship between a substrate resistivity and a width of a no-oxygen-precipitation-nucleus-forming-region in a process where low temperature annealing at 650° C. for 1 hr and medium temperature annealing under conditions of 800° C. for 4 hr and 1000° C. for 16 hr in this order were applied to silicon epitaxial wafers 50 manufactured, as described above, using p⁺ CZ substrates 1 with various resistivities. It can be seen that a width of a no-oxygen-precipitation-nucleus-forming-region 15 can be decreased to 10 μm or less in a case of a substrate resistivity of 0.012 Ω·cm or less.

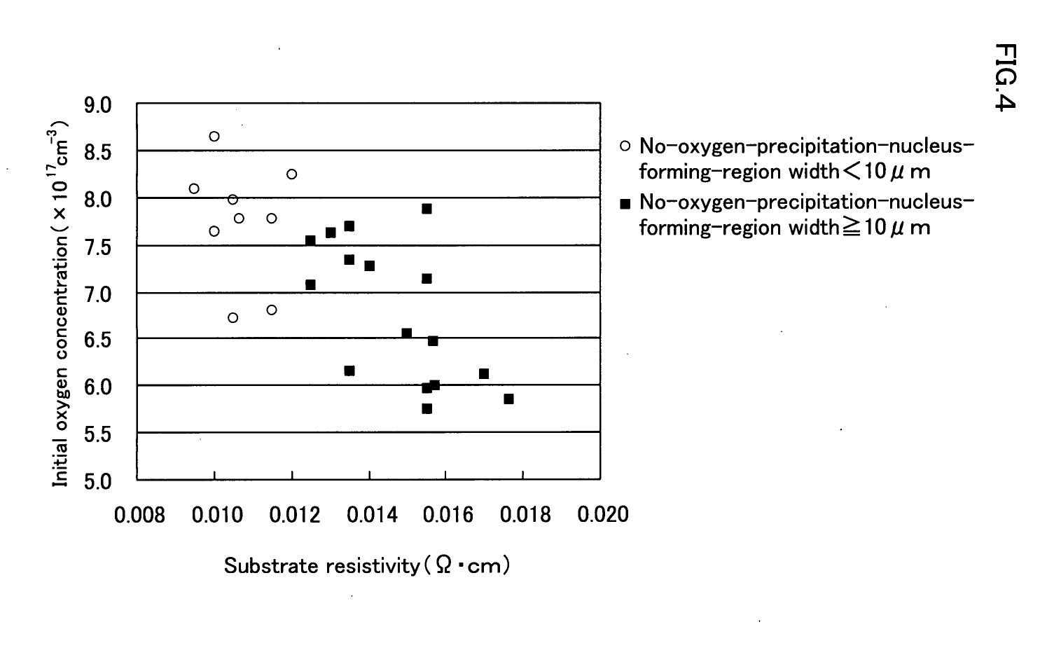

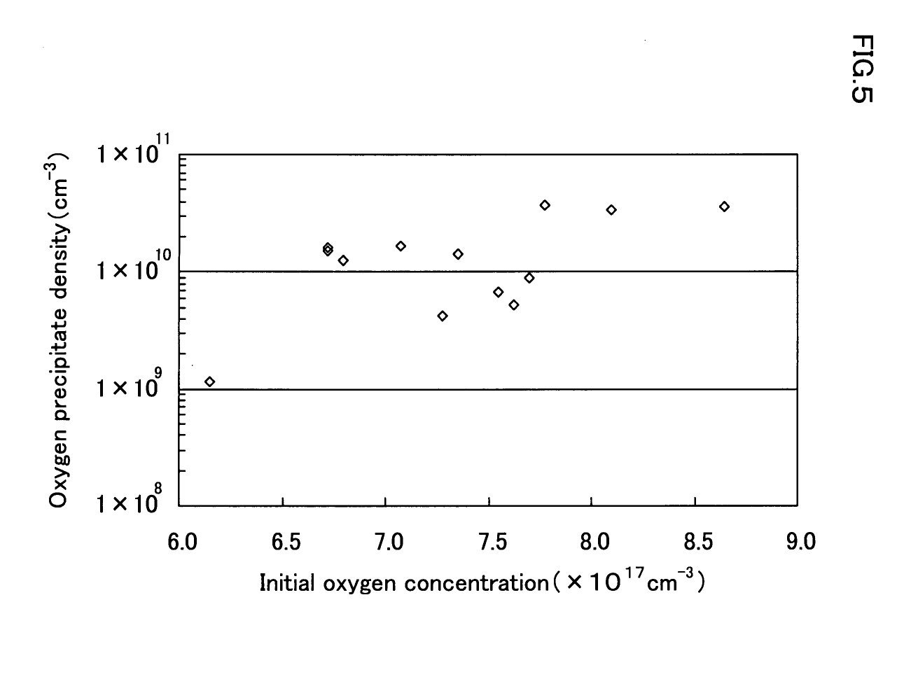

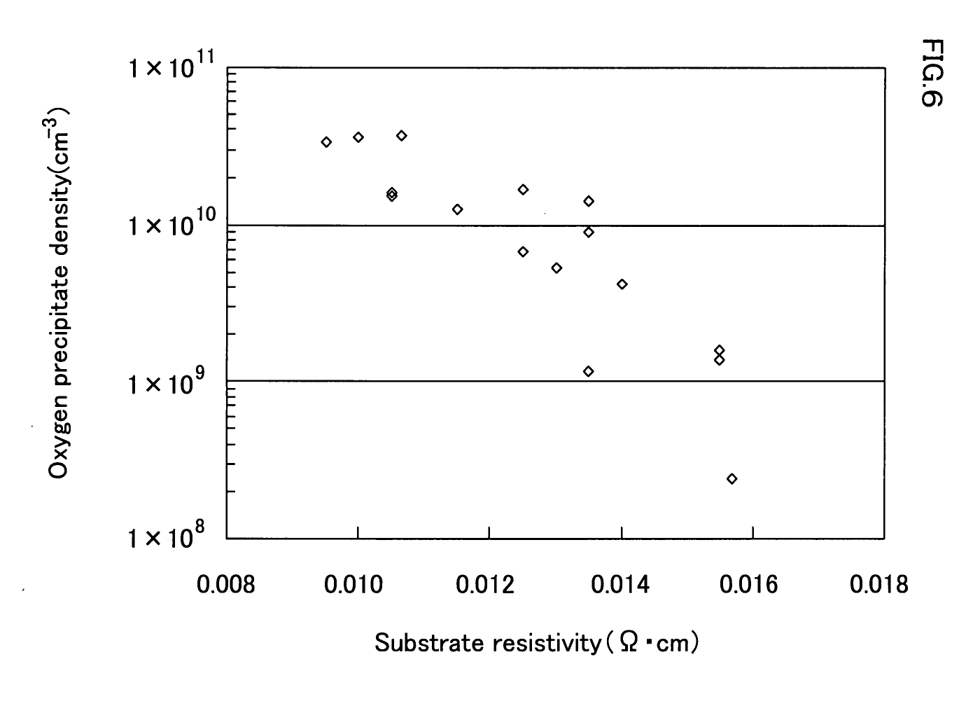

In FIG. 4, there is shown a relationship between a substrate resistivity and an initial oxygen concentration of the substrate, and it shows that with a lower substrate resistivity, the initial oxygen concentration increases. This means that with a lower substrate resistivity, more oxygen precipitates can be produced and also that a width of a no-oxygen-precipitation-nucleus-forming-region 15 is determined mainly by a value of a substrate resistivity. In FIG. 5, there is shown a relationship between an initial oxygen concentration and an oxygen precipitate density, and it can be seen that a density of oxygen precipitates gradually increases with increase in an initial oxygen concentration, and that a density of oxygen precipitates can be easily reached to 1×10¹⁰ cm⁻³ or higher at an initial oxygen concentration of 6.5×10¹⁷ cm⁻³ or higher. In FIG. 6, there is shown a relationship between a substrate resistivity and an oxygen precipitate density, and it can be seen that a substrate resistivity is desirably set to 0.012 Ω·cm or lower in order to raise a density of oxygen precipitates 12 to 1×10¹⁰ cm⁻³ or higher.

What is claimed is:

1. A silicon epitaxial wafer formed by growing a silicon epitaxial layer on a silicon single crystal substrate, produced by means of a CZ method, and doped with boron so that a resistivity thereof is in the range of 0.009 Ω·cm or higher and 0.012 Ω·cm or lower,
wherein the silicon single crystal substrate has not only oxygen precipitation nuclei at a density of 1×10¹⁰ cm⁻³ or higher, but also a width of a no-oxygen-precipitation-nucleus-forming-region, which is formed in the surface portion serving as the interface between the silicon epitaxial layer and the silicon single crystal substrate, is in the range of more than 0 μm and less than 10 μm.

2. The silicon epitaxial wafer according to claim 1, wherein a density of the oxygen precipitation nuclei is less than 1×10¹¹ cm⁻³.

3. The silicon epitaxial wafer according to claim 1, wherein a concentration of an initial oxygen concentration in the silicon single crystal substrate is in the range of 6.5×10¹⁷ cm⁻³ or higher and 10×10¹⁷ cm⁻³ or lower.

4. A manufacturing method of a silicon epitaxial wafer comprising:
a vapor phase growth step of vapor phase growing of a silicon epitaxial layer on a silicon single crystal substrate, produced by means of a Czochralski method, and doped with boron so that a resistivity thereof is in the range of 0.009 Ω·cm or higher and 0.012 Ω·cm or lower; and
a low temperature annealing step of conducting annealing at a temperature in the range of 450° C. or higher and 750° C. or lower, so that oxygen precipitation nuclei are produced at a density in the range of 1×10¹⁰ cm⁻³ or higher and less than 1×10¹¹ cm⁻³ in the silicon single crystal substrate after the vapor phase growth step.
